(19) United States
(12) Patent Application Publication
(10) Pub. No.: US 2020/0227441 A1
(43) Pub. Date: Jul. 16, 2020

(54) DISPLAY APPARATUS

(71) Applicant: Au Optronics Corporation, Hsinchu (TW)

(72) Inventors: Cheng-Te Lin, Hsinchu (TW); Chun Chang, Hsinchu (TW)

(73) Assignee: Au Optronics Corporation, Hsinchu (TW)

(21) Appl. No.: 16/535,097

(22) Filed: Aug. 8, 2019

(30) Foreign Application Priority Data
Jan. 15, 2019 (TW) 108101500

(51) Int. Cl. H01L 27/12; H01L 27/32; H01L 33/50

(52) U.S. Cl. CPC H01L 27/124; H01L 27/1251; H01L 27/3213; H01L 33/504; H01L 27/3276

(57) ABSTRACT

A display apparatus includes a first substrate, a second substrate, a display medium, first signal lines, second signal lines, read-out lines and a repeating unit. The repeating unit includes a color pixel, a white pixel and a photosensitive structure. The color pixel is electrically connected to one first signal line and one second signal line. The white pixel is electrically connected to another first signal line and the same second signal line. The photosensitive structure is electrically connected to a read-out line and the second signal line. The photosensitive structure has a first electrode, a photoelectric conversion layer and a second electrode which are sequentially stacked on the inner surface of the first substrate. The first electrode is a transparent electrode, and an outer surface of the first substrate is a display surface.

### CROSS-REFERENCE TO RELATED APPLICATION

This application claims the priority benefit of Taiwan application serial no. 108101500, filed on Jan. 15, 2019. The entirety of the above-mentioned patent application is hereby incorporated by reference herein and made a part of this specification.

### BACKGROUND

### Technical Field

The invention relates to a display apparatus.

### Description of Related Art

The principle of optical fingerprint recognition is as follows. A fingerprint is made up of a number of irregular ridges and valleys. When a finger presses on a fingerprint recognition device, the ridges contact the fingerprint recognition device, and the valleys do not contact the fingerprint recognition device. The ridges directly reflect light to a photosensitive structure to form a bright region. At the same time, light that strikes the valleys is reflected multiple times in the valleys before being transmitted to the photosensitive structure, thereby forming a dark region. As such, the lights corresponding to the ridges and the valleys of the fingerprint are formed into an interleaved bright and dark stripe pattern, so as to obtain a fingerprint image. Then, the fingerprint recognition can be performed by using an algorithm to calculate information corresponding to the fingerprint image.

An optical fingerprint recognition device includes an under-screen type and an integrated type. Taking the under-screen type as an example, because the photosensitive structure is disposed under a display panel, it leads to a problem that an overall thickness of the device is too thick. Taking the integrated type for an example, the photosensitive structure is integrated within the display panel so that the overall thickness of the device is thin, but the light from the fingerprint can be transmitted to the photosensitive structure only after passing through a display medium of the display panel, such that the light from the fingerprint is scattered by the display medium, thereby affecting the acquisition of the information of the fingerprint image.

### SUMMARY

The invention provides a display apparatus with favorable performance.

A display apparatus of the invention includes a first substrate, a second substrate, a display medium, a plurality of first signal lines, a plurality of second signal lines, a plurality of read-out lines, and at least one repeating unit. The first substrate has an inner surface and an outer surface opposite to each other. The second substrate is disposed opposite to the first substrate. The display medium is disposed between the first substrate and the second substrate. The first signal lines are disposed on the inner surface of the first substrate. The second signal lines are disposed on the inner surface of the first substrate. The first signal lines and the second signal lines are interlaced. The at least one repeating unit includes a color pixel, a white pixel and a photosensitive structure. The color pixel is disposed on the inner surface of the first substrate and electrically connected to one of the first signal lines and one of the second signal lines. The white pixel is disposed on the inner surface of the first substrate and electrically connected to another one of the first signal lines and the one of the second signal lines. The photosensitive structure is disposed on the inner surface of the first substrate and electrically connected to one of the read-out lines and the one of the second signal lines. The photosensitive structure has a first electrode, a photoelectric conversion layer and a second electrode which are sequentially stacked on the inner surface of the first substrate towards a direction of the second substrate. The first electrode is a transparent electrode, and the outer surface of the first substrate is a display surface of the display apparatus.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a top view schematic diagram of a display apparatus 10 according to an embodiment of the invention.

FIG. 2 is a schematic cross-sectional diagram of the display apparatus 10 illustrated according to a section line I-I′ of FIG. 1.

FIG. 3 is a schematic cross-sectional diagram of the display apparatus 10 illustrated according to a section line II-II′ of FIG. 1.

FIG. 4 shows a condition in which an object 1 is disposed on a display surface of the display apparatus 10 according to an embodiment of invention.

FIG. 5 shows a plurality of electrical signals SLS1, SLS2 obtained by a plurality of photosensitive structures LS of FIG. 4.

FIG. 6 shows brightnesses SPW1, SPW2 of a plurality of white pixels PW of FIG. 4.

FIG. 7 is a work flow diagram of the display apparatus 10 according to an embodiment of the invention.

### DESCRIPTION OF THE EMBODIMENTS

In the drawings, for clarity, the thickness of layers, films, plates, area, and so on are magnified. Throughout the specification, the same reference numerals indicate the same elements. It should be understood that when an element such as a layer, a film, an area, or a substrate is indicated to be “on” another element or “connected to” another element, it may be directly on another element or connected to another element, or an element in the middle may be existed. In contrast, when an element is indicated to be “directly on another element” or “directly connected to” another element, an element in the middle is not existed. For example, “connect” indicated in the specification may indicate physically and/or electrically connect. Furthermore, “electrically connect” or “coupled to” may be indicated that other element exists between two elements.

The usages of “approximately”, “similar to”, or “substantially” indicated throughout the specification include the indicated value and an average value having an acceptable deviation range, which is a certain value confirmed by people skilled in the art, and is a certain amount considered the discussed measurement and measurement-related deviation (that is, the limitation of measurement system). For example, “approximately” may be indicated that within one or more standard deviations of the value, or within ±30%, ±20%, ±10%, ±5%. Furthermore, the usages of “approximately”, “similar to” or “substantially” indicated throughout the specification may be referred to a more acceptable deviation scope or standard deviation depending on optical properties, etching properties, or other properties, and all properties may not be applied with one standard deviation.

Unless otherwise defined, the terms used throughout the specification (including both technical and scientific terms) has the same meaning understood by people skilled in the art. It should be further understood that, terms such as those defined in commonly used dictionaries should be interpreted as having meanings consistent with the meanings in the prior art and the context of the invention, and shall not be interpreted as an idealized or overly formal meaning, unless they are definitely defined in the content.

Exemplary embodiments are described herein with reference to cross section illustrations that are schematic illustrations of idealized embodiments. Therefore, variations in the shapes of the illustrations of, for example, the result of manufacturing techniques and/or tolerances, are to be expected. Thus, embodiments described herein should not be interpreted as a certain shape limited to areas illustrated in the context, but are to include deviations in shapes that result, for example, from manufacturing. For instance, illustrated or described flat areas may usually have rough and/or non-linear features. Besides, the illustrated acute angle may be round. Therefore, areas illustrated in drawing are substantially schematic, their shapes are not intended to illustrate the exact shapes of the areas, and they are not intended to limit the claimed scopes.

References of the exemplary embodiments of the invention are made in detail. Examples of the exemplary embodiments are illustrated in the drawings. If possible, the same reference numerals in the drawings and the descriptions are indicated the same or similar parts.

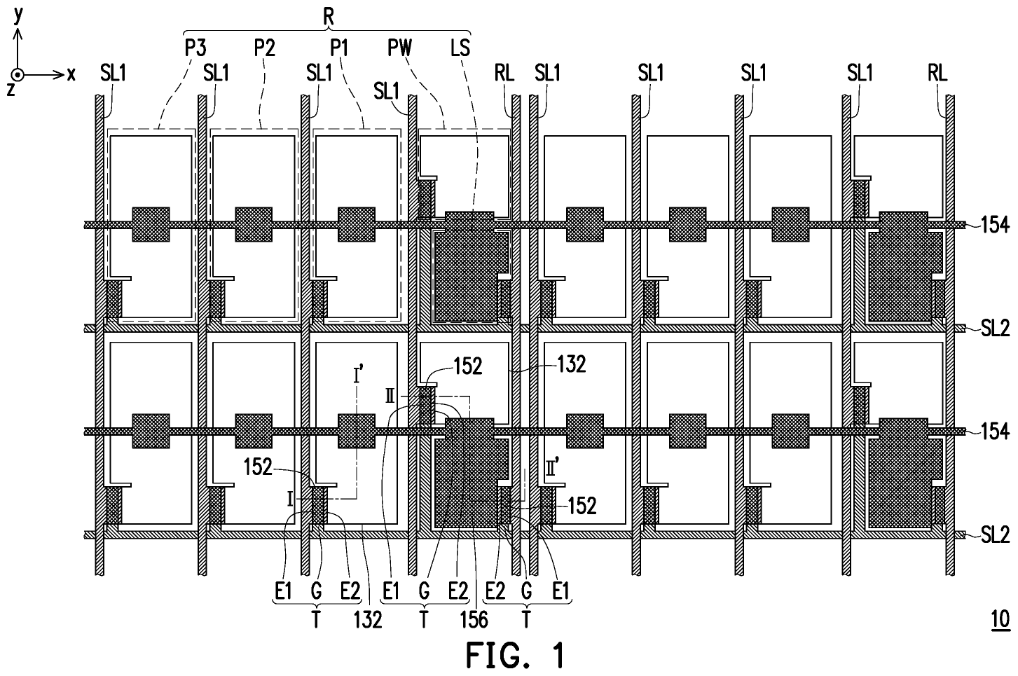

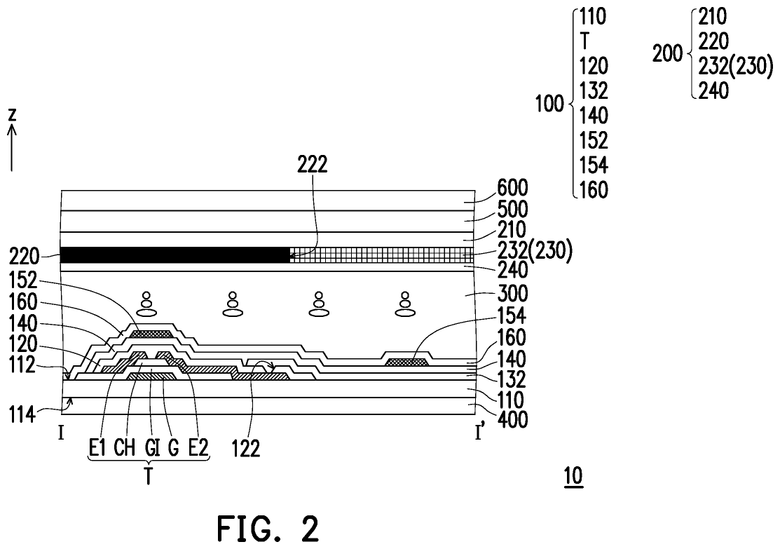

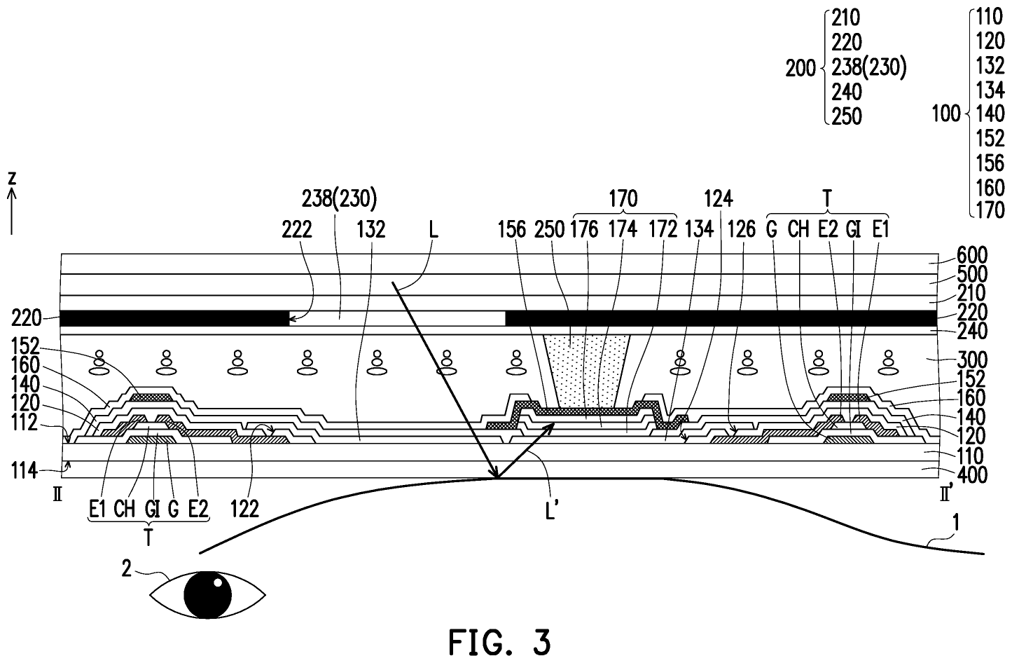

FIG. 1 is a top view schematic diagram of a display apparatus 10 according to an embodiment of the invention. FIG. 2 is a schematic cross-sectional diagram of the display apparatus 10 illustrated according to a section line I-I′ of FIG. 1. FIG. 3 is a schematic cross-sectional diagram of the display apparatus 10 illustrated according to a section line II-II′ of FIG. 1. FIG. 1 omits a first substrate 110, an insulating layer GI, an insulating layer 120, an insulating layer 140, an insulating layer 160, an opposite substrate 200, a display medium 300, a backlight source 600, a polarizer 400, and a polarizer 500 of FIG. 2 and FIG. 3.

Referring to FIG. 1 through FIG. 3, the display apparatus 10 in addition to being used for display is also used to acquire an image information of an object 1 (as illustrated in FIG. 3). That is to say, the display apparatus 10 integrates an optical imaging element (for example: an optical fingerprint image capturing element) into a display panel. In the present embodiment, the object 1 may be a biometric feature, such as: a fingerprint of a user 2 (as illustrated in FIG. 3). However, the invention is not limited thereto, and the object 1 may also be other types of biometric features, such as: veins, etc.

Referring to FIG. 2 and FIG. 3, the display apparatus 10 includes a pixel array substrate 100, an opposite substrate 200 and a display medium 300. The opposite substrate 200 is disposed opposite to the pixel array substrate 100. The display medium 300 is disposed between the pixel array substrate 100 and the opposite substrate 200. For example, in the present embodiment, the display medium 300 may be a non-self-luminous material (such as, but not limited to: liquid crystal), and the display apparatus 10 may further include the backlight source 600, the polarizer 400 and the polarizer 500, wherein the polarizer 400, the pixel array substrate 100, the display medium 300, the opposite substrate 200, the polarizer 500, and the backlight source 600 are sequentially arranged along a sight direction z of the user 2. It is to be noted that, the invention does not limit that the display medium 300 must be a non-self-luminous material and the display apparatus 10 must include the backlight source 600 and the polarizers 400 and 500. According to other embodiments, the display medium 300 may also be a self-luminous material, such as, but not limited to: an organic electroluminescent layer, a micro light-emitting diode or other types of display medium, and the display apparatus does not have to include the backlight source and/or the polarizers.

The pixel array substrate 100 includes the first substrate 110 having an inner surface 112 and an outer surface 114 opposite to each other. The inner surface 112 of the first substrate 110 faces toward the display medium 300. The outer surface 114 of the first substrate 110 faces away from the display medium 300. In the present embodiment, the pixel array substrate 100 is closers to the eyes of the user 2 than the opposite substrate 200, and the outer surface 114 of the first substrate 110 is a display surface of the display apparatus 10. The first substrate 110 is a light transmissive substrate. For example, a material of the light transmissive substrate may be glass, quartz, organic polymer or other applicable material, but the invention is not limited thereto.

Referring to FIG. 1 and FIG. 2, the pixel array substrate 100 further includes a plurality of first signal lines SL1 and a plurality of second signal lines SL2 disposed on the inner surface 112 of the first substrate 110. The first signal lines SL1 and the second signal lines SL2 are interlaced. The first signal lines SL1 extend in a first direction y, the second signal lines SL2 extend in a second direction x, and the first direction y and the second direction x are intersected. For example, in the present embodiment, the first direction y and the second direction x are substantially perpendicular, but the invention is not limited thereto. In the present embodiment, the first signal lines SL1 and the second signal lines SL2 are formed on different layers; for example, the second signal lines SL2 may selectively be formed on a first conductive layer (for example, but not limited to: a first metal layer), and the first signal lines SL1 may selectively be formed on a second conductive layer (for example, but not limited to: a second metal layer), but the invention is not limited thereto.

The pixel array substrate 100 further includes a plurality of pixels P1, P2, P3, PW. Each of the pixels P1, P2, P3 and PW is electrically connected to a corresponding first signal line SL1 and a corresponding second signal line SL2. Specifically, in the present embodiment, each of the pixels P1, P2, P3 and PW includes an active element T. The active element T includes a thin film transistor having a control end G, an insulating layer GI, a semiconductor layer CH, a first end E1, and a second end E2. The control end G and the second signal line SL2 are electrically connected. The second signal line SL2 is, for example, a scan line. The insulating layer GI is disposed between the control end G and the semiconductor layer CH, and two different regions of the semiconductor layer CH are electrically connected with the first end E1 and the second end E2 respectively. The first end E1 and the first signal line SL1 are electrically connected. The first signal line SL1 is, for example, a data line. In the present embodiment, or an example, the second signal lines SL2 and the control ends G may selectively be formed on the first conductive layer, the first signal lines SL1 and the first ends E1 and the second ends E2 of the thin film transistors may selectively be formed on the second conductive layer, but the invention is not limited thereto.

Each of the pixels P1, P2, P3 and PW further includes a pixel electrode 132 electrically connected to the active element T. Specifically, in the present embodiment, the second end E2 of the thin film transistor and the pixel electrode 132 are electrically connected. For instance, the pixel array substrate 100 may further includes the insulating layer 120 disposed on the active element T, and at least a portion of the pixel electrode 132 can be disposed on the insulating layer 120 and electrically connected to the second end E2 through a contact window 122 of the insulating layer 120. However, the invention is not limited thereto. According to other embodiments, the pixel electrode 132 may also be electrically connected to the second end E2 of the thin film transistor by other means.

The pixel array substrate 100 further includes a plurality of common electrode lines 154 disposed on the inner surface 112 of the first substrate 110. A portion of the pixel electrode 132 of each of the pixels P1, P2, P3 and PW overlaps with a corresponding common electrode line 154 to form a storage capacitor of each of the pixels P1, P2, P3 and PW. For instance, in the present embodiment, the pixel array substrate 100 further includes the insulating layer 140 disposed on the insulating layer 120 and the pixel electrodes 132, and the common electrode lines 154 may selectively be disposed on the insulating layer 140. In the present embodiment, the common electrode lines 154 may selectively be formed on a third conductive layer (for example, but not limited to: a third metal layer), but the invention is not limited thereto.

In the present embodiment, the pixel array substrate 100 may further include a light-shielding pattern 152 disposed on the insulating layer 140 and overlaps with the semiconductor layer CH. The light-shielding pattern 152 can block a light L emitted by the backlight source 600 from irradiating the semiconductor layer CH, so as to reduce an electrical leakage of the thin film transistor. In the present embodiment, the light-shielding pattern 152 may selectively be disposed on the insulating layer 140 and be formed on the third conductive layer, but the invention is not limited thereto.

Moreover, in the present embodiment, the pixel array substrate 100 may further includes the insulating layer 160 disposed on the light-shielding pattern 152 and the common electrode lines 154 for protecting the components between the the insulating layer 160 and the first substrate 110.

The opposite substrate 200 includes a second substrate 210. In the present embodiment, the second substrate 210 is a transparent substrate. The display apparatus 10 may further include a light-shielding layer 220, such as, but not limited to: a black matrix. For example, in the present embodiment, the light-shielding layer 220 can be overlapped with the active element T, the first signal line SL1, the second signal line SL2 and a read-out line RL, and have an opening 222 overlapping the pixel electrode 132. In the present embodiment, the light-shielding layer 220 may selectively be disposed on the second substrate 210. However, the invention is not limited thereto. According to other embodiments, the light-shielding layer 220 may also be disposed on the first substrate 110.

In the present embodiment, the display apparatus 10 further includes a color filter layer 230 having a first color filter pattern 232, a second color filter pattern (not shown) and a third color filter pattern (not shown). The first color filter pattern 232, the second color filter pattern and the third color filter pattern respectively have a first color, a second color and a third color. The first color, the second color and the third color include, for example, but not limited to: blue, green and red. For instance, in the present embodiment, the opposite substrate 200 may selectively include the first color filter pattern 232, the second color filter pattern and the third color filter pattern disposed on the second substrate 210. However, the invention is not limited thereto. According to other embodiments, the first color filter pattern 232, the second color filter pattern and the third color filter pattern may also be disposed on the first substrate 110.

Moreover, in the present embodiment, the color filter layer 230 further has a light transmissive material portion 238 (as illustrated in FIG. 3) disposed in the opening 222 of the light-shielding layer 220 and overlapping with the pixel electrode 132 of the pixel PW. However, the invention is not limited thereto. According to other embodiments, the opening 222 that overlaps with the pixel electrode 132 of the pixel PW may also have no light transmissive material portion 238 disposed therein.

In the present embodiment, the pixels P1, P2, P3 and PW include a first color pixel P1, a second color pixel P2, a third color pixel P3 and a white pixel PW respectively for displaying the first color, the second color, the third color and the white color. For example, in the present embodiment, the pixel electrode 132 of the first color pixel P1, the pixel electrode 132 of the second color pixel P2, the pixel electrode 132 of the third color pixel P3 and the white pixel PW can respectively overlap with the first color filter pattern 232, the second color filter pattern (not shown), the third color filter pattern (not shown) and the light transmissive material portion 238, so as to enable the first color pixel P1, the second color pixel P2, the third color pixel P3 and the white pixel PW to respectively display the first color, the second color, the third color and the white color.

Referring to FIG. 1 and FIG. 3, the pixel array substrate 100 further includes a photosensitive structure LS disposed on the inner surface 112 of the first substrate 110. For instance, in the present embodiment, vertical projections of the white pixel PW and the photosensitive structure LS on the first substrate 110 are located between vertical projections of two adjacent first signal lines SL1 on the first substrate 110 and between vertical projections of two adjacent second signal lines SL2 on the first substrate 110, but the invention is not limited thereto.

In the present embodiment, the photosensitive structure LS includes an active element T, a first electrode 134, a photoelectric conversion layer 170 and a second electrode 156. The active element T and the first electrode 134 are electrically connected. The first electrode 134, the photoelectric conversion layer 170 and the second electrode 156 are sequentially stacked on the inner surface 112 of the first substrate 110 towards the direction Z of the second substrate 210. The first electrode 134 is a light transmissive electrode, so that light L′ diffused by the object 1 can pass through the first electrode 134 and be received by the photoelectric conversion layer 170. In the present embodiment, the second electrode 156 is located between the display medium 300 and the photoelectric conversion layer 170, and the second electrode 156 is a light blocking electrode so as to prevent unnecessary light (e.g., light L emitted directly from the backlight source 600) from irradiating the photoelectric conversion layer 170, and thereby influences the acquired image information of the object 1. For instance, in the present embodiment, the photoelectric conversion layer 170 may include an N-type semiconductor layer 172, a P-type semiconductor layer 176 and an intrinsic semiconductor substrate 174 located between the N-type semiconductor layer 172 and the P-type semiconductor layer 176. In the present embodiment, the N-type semiconductor layer 172, the intrinsic semiconductor substrate 174 and the P-type semiconductor layer 176 may selectively be sequentially stacked along the sight direction z. However, the invention is not limited thereto. According to other embodiments, the N-type semiconductor layer 172, the intrinsic semiconductor substrate 174 and the P-type semiconductor layer 176 may also be sequentially stacked along a direction opposite to the sight direction z.

It is worth noted that, the pixels P1, P2, P3 and PW and the photosensitive structure LS are all disposed on the inner surface 112 of the first substrate 110, and the outer surface 114 of the first substrate 110 is a display surface. That is, the object 1 is adapted to be disposed on the display surface (namely, the outer surface 114 of the first substrate 110), and the light L′ diffused by the object 1 can be transmitted to the photoelectric conversion layer 170 of the photosensitive structure LS with having to pass through the display medium 300; namely, the light L′ diffused by the object 1 is not scattered by the display medium 300, thus obtaining good image information of the object 1.

In the present embodiment, by taking process simplification into consideration, some components of the photosensitive structure LS can be fabricated together with some components of the pixels P1, P2, P3 and PW. For example, in the present embodiment, the active element T of the photosensitive structure LS and the active elements T of the pixels P1, P2, P3 and PW may selectively be fabricated together to have the same or similar stack structures. Specifically, the active element T of the photosensitive structure LS also includes a thin film transistor, the thin film transistor also has a control end G, an insulating layer GI, a semiconductor layer CH, a first end E1 and a second end E2. The control end G of the active element T of the photosensitive structure LS may selectively be fabricated together with the control ends G of the active elements T of the pixels P1, P2, P3 and PW. The insulating layer GI of the active element T of the photosensitive structure LS may selectively be fabricated together with the insulating layers GI of the active elements T of the pixels P1, P2, P3 and PW. The semiconductor layer CH of the active element T of the photosensitive structure LS may selectively be fabricated together with the semiconductor layers CH of the active elements T of the pixels P1, P2, P3 and PW. The first end E1 and the second end E2 of the active element T of the photosensitive structure LS may selectively be fabricated together with the first ends E1 and the second ends E2 of the active elements T of the pixels P1, P2, P3 and PW.

The first electrode 134 of the photosensitive structure LS may selectively be fabricated together with the pixel electrodes 132 of the pixels P1, P2, P3 and PW. The second electrode 156 of the photosensitive structure LS may selectively be fabricated together with the common electrode lines 154 of the pixels P1, P2, P3 and PW. That is, in the present embodiment, the common electrode line 154 and the second electrode 156 of the photosensitive structure LS may both be disposed on the insulating layer 140, and a material of the common electrode line 154 is the same as a material of the second electrode 156 of the photosensitive structure LS. In addition, the active element T of the photosensitive structure LS is also disposed with the light-shielding pattern 152 that overlaps with the semiconductor layer CH of the active element T of the photosensitive structure LS; and the light-shielding pattern 152 of the active element T of the photosensitive structure LS and the light-shielding patterns 152 on the active elements T of the pixels P1, P2, P3 and PW may also be fabricated together.

In the present embodiment, in order to obtain better image information of the object 1, the first electrode 134 of the photosensitive structure LS may directly contact the inner surface 112 of the first substrate 110; that is, the insulating layer 120 has an opening 124, and the first electrode 134 of the photosensitive structure LS may be disposed in the opening 124 of the insulating layer 120; but the invention is not limited thereto.

In the present embodiment, the display apparatus 10 further includes a common electrode 240. A potential difference between the common electrode 240 and the pixel electrode 132 is used to drive the display medium 300. For example, in the present embodiment, the opposite substrate 200 may selectively include the common electrode 240 disposed on the second substrate 210, but the invention is not limited thereto.

In the present embodiment, the display apparatus 10 further includes a spacer 250 disposed between the first substrate 110 and the second substrate 210 to maintain a gap between the pixel array substrate 100 and the opposite substrate 200. For example, in the present embodiment, the opposite substrate 200 may include the space 250 that protrudes toward the first substrate 110 and is disposed on the second substrate 210, but the invention is not limited thereto.

In the present embodiment, the spacer 250 may be disposed between the second electrode 156 of the photosensitive structure LS and the second substrate 210. That is, from the view of the user 2, the spacer 250 is obscured by the second electrode 156. Therefore, a portion of the display medium 300 (e.g., liquid crystal) which is affected by the spacer 250 to have poor orientation may be shielded by the second electrode 156, and thus does not unduly affect the display quality.

It is worth noted that, in the present embodiment, the spacer 250 may be a conductive spacer. The spacer 250 is disposed between and electrically connected to the common electrode 240 and the second electrode 156 of the photosensitive structure LS. Also, the second electrode 156 of the photosensitive structure LS is electrically connected with the common electrode line 15. That is, the spacer 250 is electrically connected between the common electrode line 154 located on the first substrate 110 and the common electrode 240 located on the second substrate 210. Thereby, the common electrode line 154 located on the first substrate 110 can be electrically connected to the common electrode 240 of the opposite substrate 200 more uniformly through a plurality of conductive spacers 250, and thus is conducive for enhancing the electric property of the display apparatus 10.

The pixel array substrate 100 further includes a read-out line RL disposed on the inner surface 112 of the first substrate 110 and interlacing with the second signal lines SL2. In the present embodiment, the read-out line RL and the first signal lines SL1 are disposed in parallel, but the invention is not limited thereto. In the present embodiment, the read-out line RL and the first signal lines SL1 may selectively be fabricated together. In the present embodiment, the read-out line RL and the first signal lines SL1 can be formed on the second conductive layer, but the invention is not limited thereto.

The photosensitive structure LS is electrically connected to the read-out line RL and the second signal line SL2. Specifically, the first end E1 of the active element T of the photosensitive structure LS is electrically connected with the read-out line RL, and a gate G of the active element T of the photosensitive structure LS is electrically connected with the second signal line SL2. In addition, the second end E of the active element T of the photosensitive structure LS is electrically connected with the first electrode 134. For instance, the insulating layer 120 has a contact window 126, and the first electrode 134 of the photosensitive structure LS can be electrically connected to the second end E2 of the active element T through the contact window 126 of the insulating layer 120. However, the invention is not limited thereto. According to other embodiment, the first electrode 134 of the photosensitive structure LS may also be electrically connected to the second end E2 of the active element T by using other means.

For example, in the present embodiment, a repeating unit R (as indicated in FIG. 1) includes at least one of each respective color pixels P1, P2 and P3, one white pixel PW and one photosensitive structure LS. The pixel array substrate 100 may further has a plurality of repeating units R arranged in an array. Within a frame time, the second signal lines SL2 of the pixel array substrate 100 can be sequentially input into a gate turn-on signal in a plurality of time intervals, so that the active elements T of the color pixels P1, P2 and P3 and the white pixels PW that are respectively located in a plurality of columns are sequentially turned on during the time intervals, thereby displaying the picture. Within the time intervals, the active elements T of the photosensitive structures LS respectively located in the columns are sequentially turned on, so as to enable the read-out lines RL to access electrical signals from the photoelectric conversion layer 170 during the time intervals, thereby obtaining the image information of the object 1.

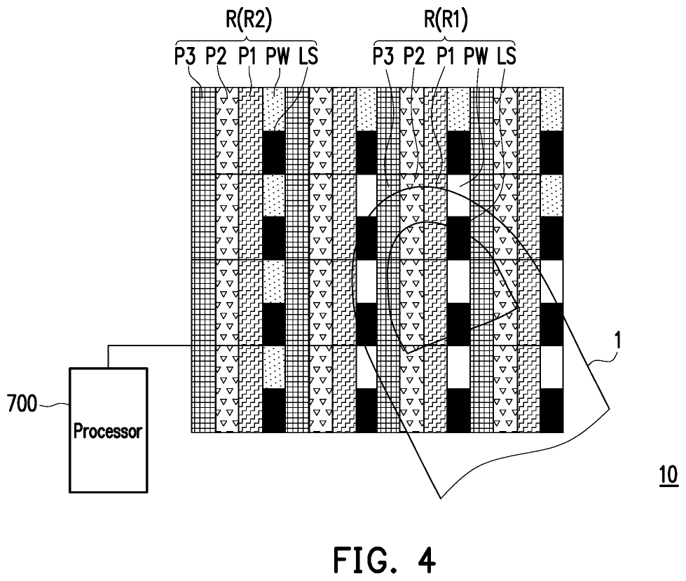

It is worth noted that, as shown in FIG. 1, in the present embodiment, the gate G of the active element T of the photosensitive structure LS and the gate G of the active element T of the white pixel PW that are located in the same repeating unit R are electrically connected to the same second signal line SL2. That is, when the active element T of the photosensitive structure LS is turned on (namely, when the electrical signal on the photoelectric conversion layer 170 of the photosensitive structure LS is being accessed), the active element T of the white pixel PW is also turned on. At this moment, if the first signal line SL1 electrically connected with the active element T of the white pixel PW is enable to have an appropriate drive signal, then the white pixel PW disposed adjacent to the photosensitive structure LS can have a certain brightness. The white pixel PW with the certain brightness can irradiate the object 1, such that an intensity of the light U diffused by the object 1 increases, thereby enhancing the quality of the acquired image information of the object 1. To be brief, in the present embodiment, the display apparatus 10 can use the light L coming from the white pixel PW to supplement the illumination of the object 1 so as to enhance a recognition success rate, such as described in details below with reference to FIG. 4 through FIG. 7.

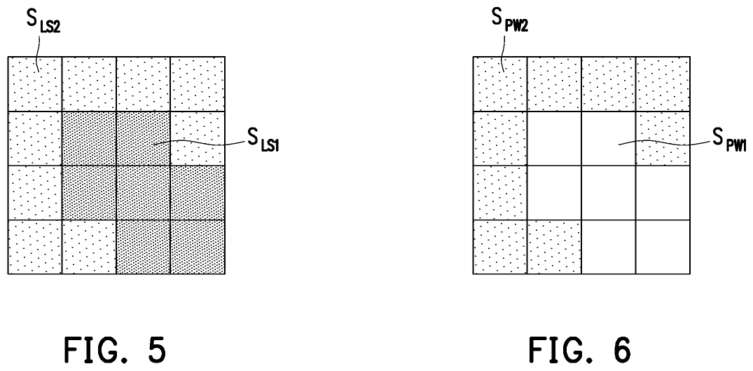

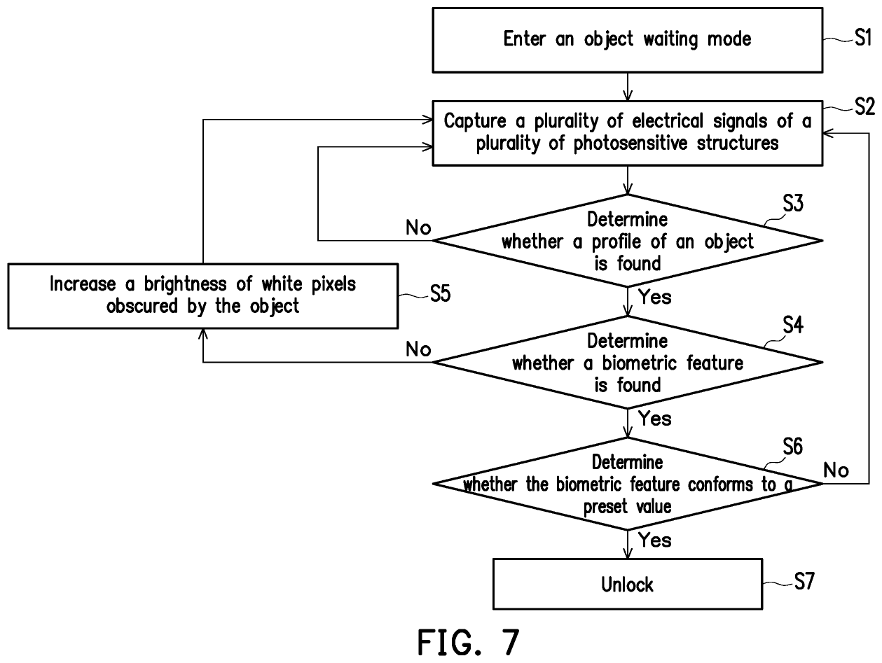

FIG. 4 shows a condition in which an object 1 is disposed on a display surface of the display apparatus 10 according to an embodiment of invention. FIG. 4 schematically shows the color pixels P1, P2 and P3, the white pixel PW, the photosensitive structure LS and a processor 700 while omits other components of the display apparatus 10. FIG. 5 shows a plurality of electrical signals SLS1 and SLS2 (or grayscale values) obtained by the photosensitive structures LS of FIG. 4, wherein dot patterns with higher density signify a lower grayscale value, and dot patterns with lower density signify a higher grayscale value. FIG. 6 shows brightnesses SPW1 and SPW2 (or grayscale values) of the white pixel PW of FIG. 4, wherein dot patterns signify the lower brightness SPW2, and blank patterns signify the higher brightness SPW1. FIG. 7 is a work flow diagram of the display apparatus 10 according to an embodiment of the invention.

Referring to FIG. 4, the display apparatus 10 further includes the processor 700, such as, but not limited to: a chip. The processor 700 is electrically connected to the read-out lines RL (as shown in FIG. 1). The processor 700 is also electrically connected to the first signal lines SL1 that are electrically connected to the white pixels PW (as shown in FIG. 1). Referring to FIG. 4 through FIG. 7, firstly, the display apparatus 10 executes a step S1: entering an object waiting mode. Next, the display apparatus 10 executes a step S2 and a step S3: capturing a plurality of the electrical signals SLS1 and SLS2 of the photosensitive structures LS (as shown in FIG. 5), and determining whether a profile of the object 1 is found (for example, but not limited to: a fingerprint profile). Specifically, the processor 700 accesses the electrical signals SLS1 and SLS2 of the photosensitive structures LS through the read-out lines RL, and determine whether a profile of the object 1 is found according to the electrical signals SLS1 and SLS2. If the profile of the object 1 is not found, then the step S2 is executed again. If the profile of the object 1 is found, then the display apparatus 10 executes a step S4: determining whether a biometric feature (for example, but not limited to: a fingerprint) of the object 1 is found. If the biometric feature of the object 1 is not found, then the display apparatus 10 executes a step S5: increasing the brightness of the white pixels PW obscured by the object 1 (as shown in FIG. 6), so as to use the light L coming from the white pixels PW (as indicated in FIG. 3) to supplement an amount of light illuminated on the object 1. Specifically, the processor 700 determines that the white pixels PW of a portion of the repeating units R (such as: first repeating units R1, as indicated in FIG. 4) are obscured by the object 1 and the white pixels PW of another portion of the repeating units R (such as: second repeating units R2, as indicated in FIG. 4) are not obscured by the object 1 according to the electrical signals SLS1 and SLS2 of the read-out lines RL; and then, the processor 700 enables the brightness SPW1 of the white pixels PW of the first repeating units R1 that are not obscured by the object 1 to increase through the first signal lines SL1, so as to use the lights L coming from the white pixels PW located under the object 1 to supplement the amount of light illuminated on the object 1. For example, in the present embodiment, the processor 700 can enable the brightness SPW1 of the white pixels PW of the first repeating units R1 that are not obscured by the object 1 to be greater than the brightness SPW2 of the white pixels PW of the second repeating unit R2 that are not obscured by the object 1 according to the electrical signals SLS1 and SLS2 of the read-out lines RL, but the invention is not limited thereto. After the step S5 is executed, the steps S2, S3 and S4 are then repeated until a biometric feature of the object 1 is found. If the biometric feature of the object 1 is found, then it is to execute a step S6: determining whether the biometric feature conforms to a preset value, such as, but not limited to: determine whether the biometric feature matches a fingerprint of the owner of the display apparatus 10. If the biometric feature conforms to the preset value, then it is to execute a step S7: unlock, allowing the user 2 (as indicated in FIG. 3) to use the display apparatus 10. If it is determined in the step S6 that the biometric feature does not conform to the preset value, then the step S2 is to be repeated again.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A display apparatus, comprising:
a first substrate, having an inner surface and an outer surface opposite to each other;
a second substrate, disposed opposite to the first substrate;
a display medium, disposed between the first substrate and the second substrate;
a plurality of first signal lines, disposed on the inner surface of the first substrate;
a plurality of second signal lines, disposed on the inner surface of the first substrate, wherein the first signal lines is interlaced with the second signal lines;
a plurality of read-out lines, disposed on the inner surface of the first substrate, wherein the read-out lines interlaces with the second signal lines; and
at least one repeating unit, the at least one repeating unit comprising:
a color pixel, disposed on the inner surface of the first substrate and electrically connected to one of the first signal lines and one of the second signal lines;
a white pixel, disposed on the inner surface of the first substrate and electrically connected to another one of the first signal lines and the one of the second signal lines; and
a photosensitive structure, disposed on the inner surface of the first substrate and electrically connected to one of the read-out lines and the one of the second signal lines,
wherein the photosensitive structure has a first electrode, a photoelectric conversion layer and a second electrode which are sequentially stacked on the inner surface of the first substrate towards a direction of the second substrate, the first electrode is a transparent electrode, and the outer surface of the first substrate is a display surface of the display apparatus.

2. The display apparatus as recited in claim 1, wherein the second electrode is disposed between the display medium and the photoelectric conversion layer, and the second electrode is a light blocking electrode.

3. The display apparatus as recited in claim 1, further comprising:
a spacer, disposed between the second electrode of the photosensitive structure and the second substrate.

4. The display apparatus as recited in claim 3, wherein the spacer is a conductive spacer.

5. The display apparatus as recited in claim 4, further comprising:
a common electrode, disposed on the second substrate, wherein the conductive spacer is disposed between the common electrode and the second electrode of the photosensitive structure.

6. The display apparatus as recited in claim 5, wherein the conductive spacer is electrically connected to the common electrode and the second electrode of the photosensitive structure.

7. The display apparatus as recited in claim 5, further comprising:
a common electrode line, disposed on the inner surface of the first substrate and overlapping with a portion of the color pixel and a portion of the white pixel, wherein the spacer is electrically connected to the common electrode line and the common electrode.

8. The display apparatus as recited in claim 4, further comprising:
an insulating layer, disposed on the first signal lines and the second signal lines; and
a common electrode line, overlapping with a portion of the color pixel and a portion of the white pixel, wherein the common electrode line and the second electrode of the photosensitive structure are disposed on the insulating layer, and a material of the common electrode line is the same as a material of the second electrode of the photosensitive structure.

9. The display apparatus as recited in claim 1, wherein the at least one repeating unit comprises a first repeating unit, and the display apparatus further comprises:
a processor, electrically connected to the read-out lines,
wherein an object is disposed on the outer surface of the first substrate and covers a photosensitive structure of the first repeating unit, and the processor causes a brightness of a white pixel of the first repeating unit to increase according to a plurality of electrical signals of the read-out lines.

10. The display apparatus as recited in claim 9, wherein the at least one repeating unit further comprises a second repeating unit, the object does not cover a photosensitive structure of the second repeating unit, and the processor causes the brightness of the white pixel of the first repeating unit to be greater than a brightness of a white pixel of the second repeating unit according to the electrical signals of the read-out lines.
